(19) United States
(12) Patent Application Publication
(10) Pub. No.: US 2024/0215219 A1
(43) Pub. Date: Jun. 27, 2024

(54) SEMICONDUCTOR DEVICE

(71) Applicant: SK hynix Inc., Gyeonggi-do (KR)

(72) Inventors: Dong Il SONG, Gyeonggi-do (KR); Seung Hwan KIM, Gyeonggi-do (KR)

(21) Appl. No.: 18/323,413

(22) Filed: May 25, 2023

(30) Foreign Application Priority Data
Dec. 22, 2022 (KR) 10-2022-0181553

(51) Int. Cl. H10B 12/00

(52) U.S. Cl. CPC H10B 12/30

(57) ABSTRACT

A semiconductor device includes a pair of word line separation slits; a word line stack disposed between the pair of the word line separation slits and including a plurality of word lines that are vertically stacked; a plurality of supporters disposed between the word line separation slits and supporting the word line stack; and contact plugs electrically connected to the word line stack.

### CROSS-REFERENCE TO RELATED APPLICATIONS

The present application claims priority of Korean Patent Application No. 10-2022-0181553, filed on Dec. 22, 2022, which is incorporated herein by reference in its entirety.

### BACKGROUND

### 1. Field

Various embodiments of the present invention relate generally to a semiconductor device, and more particularly, to a semiconductor device having a three-dimensional (3D) structure.

### 2. Description of the Related Art

In order to cope with the recent demands for large capacity and miniaturization of memory devices, various techniques for providing a three-dimensional (3D) memory device in which a plurality of memory cells are stacked have been suggested. However, many challenges remain relating to the various configurations, capacity, manufacturing and performance characteristics of 3D memory systems.

### SUMMARY

Various embodiments of the present invention as described below are directed to a highly integrated semiconductor device.

In accordance with a first embodiment of the present invention, a semiconductor device includes: a pair of word line separation slits; a word line stack disposed between the pair of the word line separation slits and including a plurality of word lines that are vertically stacked; a plurality of supporters disposed between the word line separation slits and supporting the word line stack; and contact plugs electrically connected to the word line stack.

In accordance with a second embodiment of the present invention, a semiconductor device includes: a pair of word line separation slits; a cell array portion including a plurality of vertical isolation portions; a contact portion horizontally spaced apart from the cell array portion; a word line stack including a word line main portion which is disposed in the cell array portion and a word line edge portion which is disposed between the pair of the word line separation slits; a plurality of supporters disposed between the word line separation slits and supporting the word line edge portion of the word line stack; and contact plugs electrically connected to the word line edge portion of the word line stack.

These and other features and advantages of the present invention semiconductor device will become apparent from the following detailed description and drawings of specific embodiments of the present invention.

### BRIEF DESCRIPTION OF THE DRAWINGS

FIG. 1 is a schematic plan view illustrating a semiconductor device in accordance with an embodiment of the present invention.

FIG. 2 is a cross-sectional view taken along a line A-A′ shown in FIG. 1.

FIG. 3 is a cross-sectional view taken along a line B-B′ shown in FIG. 1.

FIG. 4 is a cross-sectional view taken along a line C-C′ shown in FIG. 1.

FIGS. 5 to 8 are plan views illustrating semiconductor devices in accordance with other embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to an embodiment of the present invention described below, memory cells may be vertically stacked to increase memory cell density and reduce parasitic capacitance.

The following embodiments of the present invention described below may improve bending of a word line edge portion by forming a plurality of supporters HSL, VSL, and THSL.

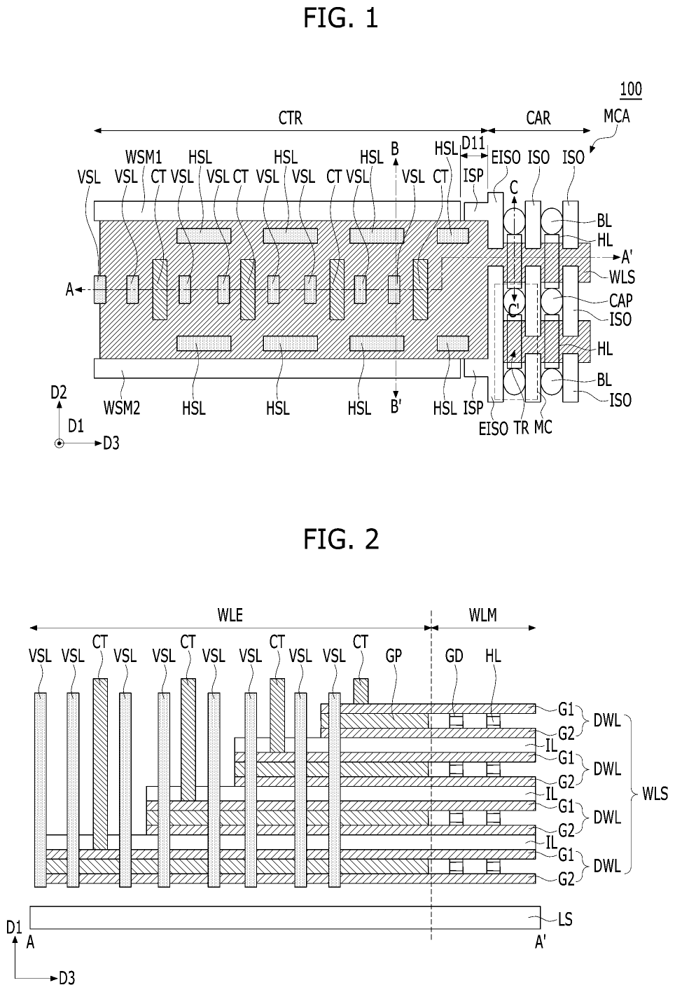

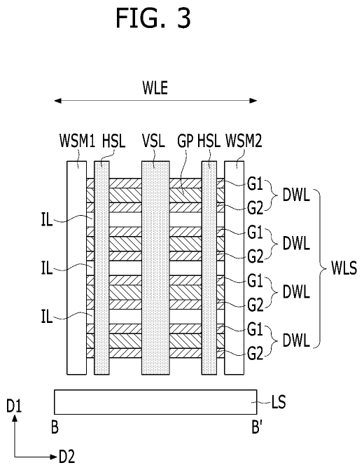

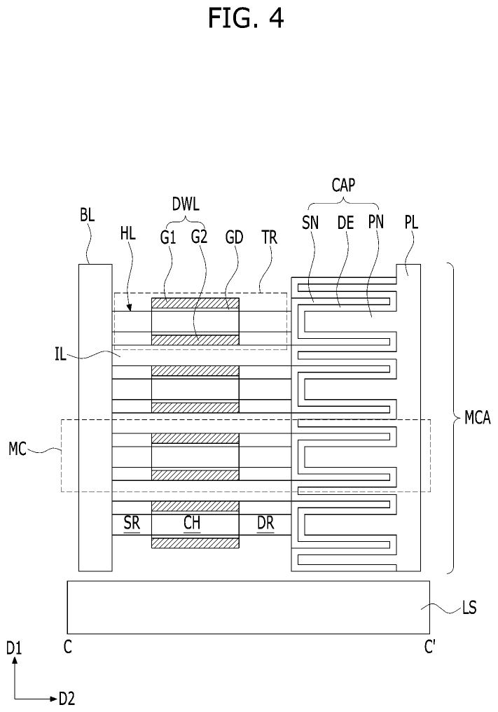

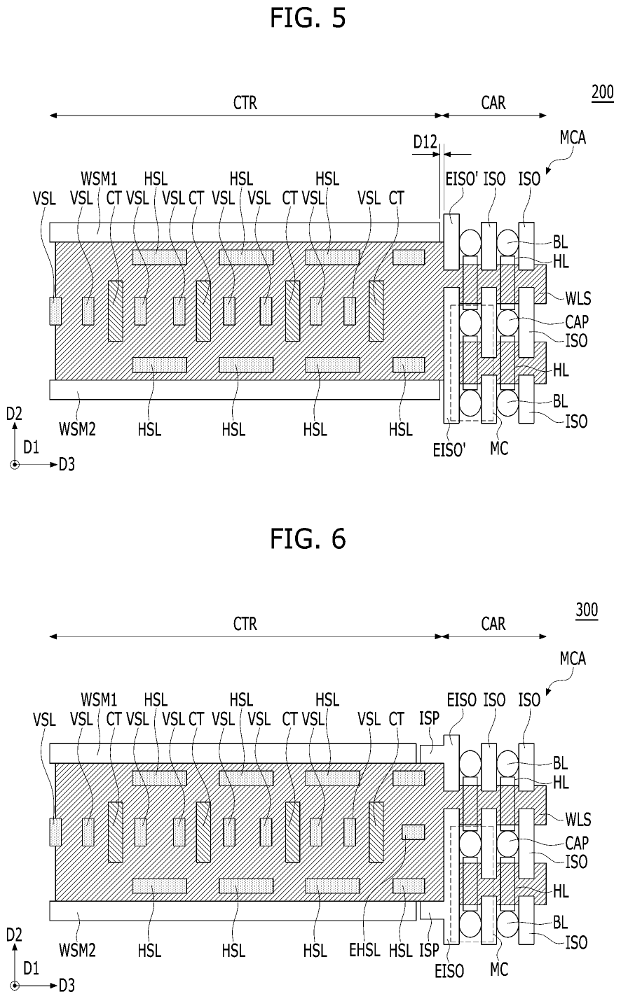

FIG. 1 is a schematic plan view illustrating a semiconductor device 100 in accordance with an embodiment of the present invention. FIG. 2 is a cross-sectional view taken along a line A-A′ shown in FIG. 1. FIG. 3 is a cross-sectional view taken along a line B-B′ shown in FIG. 1. FIG. 4 is a cross-sectional view taken along a line C-C′ shown in FIG. 1.

Referring to FIGS. 1 to 4, the semiconductor device 100 may include a memory cell array MCA. The memory cell array MCA may include a plurality of memory cells MC. The memory cell array MCA may include a three-dimensional (3D) array of the memory cells MC. The 3D array of memory cells MC may include a column array and a row array.

The memory cell array MCA may include a word line stack WLS, a plurality of bit lines BL, a plurality of transistors TR, and a plurality of capacitors CAP. The memory cell array MCA may share one word line stack WLS. Each memory cell MC may include a bit line BL, a transistor TR, and a capacitor CAP. The bit line BL may also be referred to as a vertical conductive line. The capacitor CAP may also be referred to as a data storage element.

Each transistor TR may include an active layer HL and a word line DWL. The word line DWL may include a double word line structure. For example, the double word line structure of the word line DWL may include a pair of a first word line G1 and a second word line G2. The first word line G1 and the second word line G2 may perpendicularly face each other in a first direction D1 with the active layer HL interposed therebetween. The first word line G1 may be referred to as an upper-level word line. The second word line G2 may be referred to as a lower-level word line. The word line DWL may be referred to as a horizontal conductive line. The active layer HL may be referred to as a horizontal layer.

Each capacitor CAP may include a storage node SN, a dielectric layer DE, and a plate node PN.

The bit line BL may have a pillar shape extending in the first direction D1. The active layer HL may have a bar shape extending in a second direction D2 intersecting with the first direction D1. The word line DWL may have a line shape extending in a third direction D3 intersecting with the first and second directions D1 and D2. The plate nodes PN of the capacitors CAP may be coupled to each other to be coupled to the plate lines PL.

The bit line BL may be vertically oriented in the first direction D1. The bit line BL may be referred to as a vertically oriented bit line or a pillar-shaped bit line. The bit line BL may include a conductive material. The bit line BL may include a silicon-based material, a metal-based material, or a combination thereof. The bit line BL may include silicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a TiN/W stack including titanium nitride and tungsten over titanium nitride.

The word line DWL may extend in the third direction D3. The active layer HL may extend in the second direction D2. The active layer HL may be horizontally arranged in the second direction D2 from the bit line BL. A gate dielectric layer GD may be formed on the upper and lower surfaces of the active layer HL.

The transistor TR may be a cell transistor and may have a word line DWL. In the word line DWL, the same voltage may be applied to the first word line G1 and the second word line G2. For example, a first word line G1 and a second word line G2 may form a pair. The same word line driving voltage may be applied to the first word line G1 and the second word line G2. As described above, the memory cell MCA according to the embodiment of the present invention may have a word line DWL having a double word line structure in which the first and second word lines G1 and G2 are disposed adjacent to an active layer HL.

The active layer HL may include a semiconductor material. The active layer HL may include a silicon-containing layer or a silicon germanium-containing layer. For example, the active layer HL may include silicon, monocrystalline silicon, doped polysilicon, undoped polysilicon, amorphous silicon, silicon germanium, or a combination thereof. According to another embodiment of the present invention, the active layer HL may include nano-wires or nano-sheets. The nano-wires and nano-sheets may be formed of a semiconductor material. According to another embodiment of the present invention, the active layer HL may include an oxide semiconductor material, such as indium gallium zinc oxide (IGZO). The active layer HL may include a channel CH, a first source/drain region SR, and a second source/drain region DR. The first source/drain region SR and the second source/drain region DR may be formed in the active layer HL by an impurity ion implantation process or a plasma doping process. The channel CH may vertically overlap with the first and second word lines G1 and G2.

Each of the first and second word lines G1 and G2 may include notched sidewalls facing each other.

The active layer HL may have a thickness which is smaller than the thicknesses of the first and second word lines G1 and G2. In other words, the vertical thickness of the active layer HL in the first direction D1 may be smaller than the vertical thickness of each of the first and second word lines G1 and G2 in the first direction D1. The thin active layer HL, which is described above, may be referred to as a thin-body active layer.

The gate dielectric layer GD may be formed of silicon oxide, silicon nitride, a metal oxide, a metal oxynitride, a metal silicate, a high-k material, or a ferroelectric material, an anti-ferroelectric material, or a combination thereof. The gate dielectric layer GD may include SiO₂, Si₃N₄, HfO₂, Al₂O₃, ZrO₂, AlON, HfON, HfSiO, HfSiON, or HfZrO.

The word line DWL may include a metal, a metal alloy, or a semiconductor material. The word line DWL may include, for example, titanium nitride, tungsten, polysilicon, or a combination thereof. For example, the word line DWL may include a TiN/W stack in which titanium nitride and tungsten are sequentially stacked. The word line DWL may include an N-type work function material or a P-type work function material. The N-type work function material may have a low work function of approximately 4.5 eV or less. The P-type work function material may have a high work function of approximately 4.5 eV or more.

The capacitor CAP may be disposed horizontally from the transistor TR in the second direction D2. The capacitor CAP may include a storage node SN extending horizontally from the active layer HL in the second direction D2. The capacitor CAP may further include a dielectric layer DE and a plate node PN over the storage node SN. The storage node SN, the dielectric layer DE, and the plate node PN may be horizontally arranged in the second direction D2. The storage node SN may have a horizontally oriented cylinder-shape. The dielectric layer DE may conformally cover the inner and outer walls of the cylindrical shape of the storage node SN. The plate node PN may have a shape extending toward the cylindrical inner wall and the cylindrical outer wall of the storage node SN over the dielectric layer DE. The plate node PN may be coupled to the plate line PL. The storage node SN may be electrically connected to the active layer HL.

The storage node SN has a three-dimensional (3D) structure. The storage node SN of the three-dimensional structure may have a horizontal three-dimensional structure which is oriented in the second direction D2. As an example of the 3D structure, the storage node SN may have a cylindrical shape. According to another embodiment of the present invention, the storage node SN may have a pillar shape or a pylinder shape. The pylinder shape may refer to a structure in which a pillar shape and a cylindrical shape are merged.

The storage node SN and the plate node PN may include a metal, a noble metal, a metal nitride, a conductive metal oxide, a conductive noble metal oxide, a metal carbide, a metal silicide, or a combination thereof. For example, the storage node SN and the plate node PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, and a tungsten nitride/tungsten (WN/W) stack. The plate node PN may include a combination of a metal-based material and a silicon-based material. For example, the plate node PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the storage node SN over titanium nitride, and titanium nitride (TiN) may be a plate node PN of a capacitor CAP, and tungsten nitride may be a low-resistance material.

The dielectric layer DE may be referred to as a capacitor dielectric layer. The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9. The dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including at least zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including at least hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present invention, the dielectric layer DE may include a laminated structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a stack structure, a laminated structure, or a mixed structure including zirconium oxide, hafnium oxide, and aluminum oxide.

According to another embodiment of the present invention, the dielectric layer DE may include a ferroelectric material or an anti-ferroelectric material.

According to another embodiment of the present invention, an interface control layer for improving leakage current may be further formed between the storage node SN and the dielectric layer DE. The interface control layer may include, for example, titanium oxide (TiO₂), niobium oxide, or niobium nitride. The interface control layer may also be formed between the plate node PN and the dielectric layer DE.

The capacitor CAP may include a Metal-Insulator-Metal (MIM) capacitor.

The capacitor CAP may be replaced with another data storage element. For example, the data storage element may be a phase change material, a magnetic tunnel junction (MTJ), or a variable resistance material.

The active layers HL stacked in the first direction D1 may commonly contact one bit line BL. The active layers HL neighboring in the third direction D3 may share the word line DWL. The capacitors CAP may be coupled to the active layers HL, respectively. The capacitors CAP may share one plate line PL. Each active layer HL may be thinner than each of the first and second word lines G1 and G2 of the word line DWL.

In the memory cell array MCA, a plurality of word lines DWL may be vertically stacked in the first direction D1. Each word line DWL may include a pair of a first word line G1 and a second word line G2. Between the first word line G1 and the second word line G2, a plurality of active layers HL may be arranged horizontally in the third direction D2 to be spaced apart from each other.

The lower structure LS may be a material appropriate for semiconductor processing. The lower structure LS may include at least one of a conductive material, a dielectric material, and a semiconductor material. The lower structure LS may include a semiconductor substrate. The semiconductor substrate may be formed of a silicon-containing material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure LS may include other semiconductor materials, such as germanium. The substrate LS may include a III/V-group semiconductor substrate, for example, a compound semiconductor substrate, such as GaAs. The lower structure LS may include a silicon-on-insulator (SOI) substrate.

According to another embodiment of the present invention, the lower structure LS may include peripheral circuits. The peripheral circuits may include a plurality of peripheral circuit transistors. The peripheral circuits may be disposed at a lower level than the memory cell array MCA. This may be referred to as a cell-over-PERI (COP) structure. The peripheral circuits may include at least one control circuit for driving the memory cell array MCA. The at least one control circuit of the peripheral circuits may include an N-channel transistor, a P-channel transistor, a CMOS circuit, or a combination thereof. The at least one control circuit of the peripheral circuit unit PERI may include an address decoder circuit, a read circuit, a write circuit, and the like. The at least one control circuit of the peripheral circuits may include a planar channel transistor, a recess channel transistor, a buried gate transistor, a fin channel transistor (FinFET), and the like.

For example, peripheral circuits may include sub-word line drivers and a sense amplifier. The word line DWL may be coupled to a sub-word line driver. The bit lines BL may be coupled to a sense amplifier.

The memory cell array MCA may include a cell array portion CAR and a contact portion CTR. The word line stack WLS may include a plurality of word lines DWL. For example, the word line stacks WLS may include four word lines DWL that are stacked in the first direction D1. Each of the word lines DWL may include a first word line G1 and a second word line G2. Horizontal-level dielectric layers IL may be disposed between the word lines DWL. Active layers HL may be disposed between the first word line G1 and the second word line G2 in the cell array portion CAR.

The word line stack WLS may extend from the cell array portion CAR to the contact portion CTR. In other words, the word line stack WLS may include a word line main portion WLM disposed in the cell array portion CAR, and a word line edge portion WLE disposed in the contact portion CTR.

Each of the word line edge portions WLE may have a stepped structure including a plurality of word line pad portions GP. The horizontal length may gradually decrease as it goes from the word line pad portion GP of the lowest level toward the word line pad portion GP of the highest level. Here, the horizontal length may refer to a length in the third direction D3. The word line edge portion WLE may include a first word line G1, a second word line G2, and a word line pad portion GP disposed between the first word line G1 and the second word line G2. In other words, in the contact portion CTR, the gate dielectric layers GD and the active layers HL between the first word line G1 and the second word line G2 may be removed. The space from which the gate dielectric layers GD and the active layers HL are removed may be filled with the word line pad portion GP.

Contact plugs CT may be coupled to the word line edge portions WLE. For example, the contact plugs CT may be electrically connected to the first word lines G1.

The semiconductor device 100 may further include word line separation slits WSM1 and WSM2, supporters HSL and VSL, and a plurality of isolation portions ISO.

The isolation portions ISO may be disposed in the cell array portion CAR. The isolation portions ISO may be disposed between the neighboring bit lines BL in the third direction D3. The isolation portions ISO may be disposed between the neighboring capacitors CAP in the third direction D3. The semiconductor device 100 may further include edge isolation portions EISO. The edge isolation portions EISO may be disposed at the boundary between the cell array portion CAR and the contact portion CTR. The edge isolation elements EISO may include protrusions ISP. The protrusions ISP may be disposed between the cell array portion CAR and the word line separation slits WSM1 and WSM2. According to another embodiment of the present invention, the protrusions ISP may be omitted, and in this case, the word line separation slits WSM1 and WSM2 may further extend toward the cell array portion CAR.

The isolation portions ISO, the edge isolation portions EISO, and the protrusions ISP may include silicon oxide, silicon carbon oxide, silicon nitride, a low-k material, or a combination thereof.

The word line separation slits WSM1 and WSM2 and the supporters HSL and VSL may be disposed in the contact portion CTR. The word line separation slits WSM1 and WSM2 may extend in the third direction D3. The word line separation slits WSM1 and WSM2 may include a first word line separation slit WSM1 and a second word line separation slit WSM2. A plurality of supporters HSL and VSL may be disposed between the first word line separation slit WSM1 and the second word line separation slit WSM2.

The supporters HSL and VSL may extend vertically in the first direction D1. The supporters HSL and VSL may include first supporters HSL and second supporters VSL. From the perspective of a top view, the first supporters HSL may extend in the third direction D3, and the second supporters VSL may extend in the second direction D2. As described above, the first supporters HSL and the second supporters VSL may be disposed in directions intersecting with each other. The first supporters HSL may be disposed adjacent to the word line separation slits WSM1 and WSM2. The second supporters VSL may be disposed adjacent to the contact plugs CT. The first supporters HSL may be referred to as large supporters. The second supporters VSL may be referred to as small supporters. The supporters HSL and VSL may be formed by filling supporter holes with a dielectric material. The forming of the supporters HSL and VSL may include forming a supporter hole in the contact portion CTR, removing the gate dielectric layers GD and the active layers HL between the first word line G1 and the second word line G2 through the supporter hole, forming the word line pad portion GP in the space from which the gate dielectric layers GD and the active layers HL are removed, that is, the space between the first word line G1 and the second word line G2, and forming the supporters HSL and VSL in the supporter hole.

The word line separation slits WSM1 and WSM2 and the supporters HSL and VSL may be formed of a dielectric material. For example, each of the word line separation slits WSM1 and WSM2 and the supporters HSL and VSL may include silicon oxide, silicon carbon oxide, silicon nitride, a low-k material, or a combination thereof.

The horizontal-level dielectric layers IL may extend from the cell array portion CAR to the contact portion CTR.

The word line pad portions GP may include a conductive material. The word line pad portions GP may include a metal, a metal alloy, or a semiconductor material. The word line pad portions GP may include, for example, titanium nitride, tungsten, polysilicon, or a combination thereof. For example, the word line pad portions GP may include a TiN/W stack in which titanium nitride and tungsten are sequentially stacked.

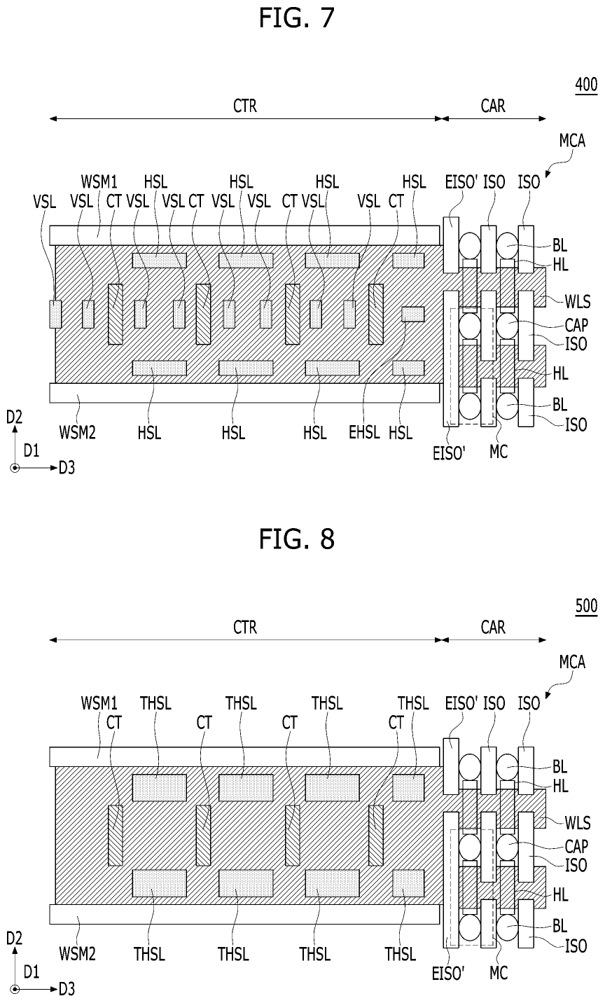

FIG. 5 is a plan view illustrating semiconductor device in accordance with another embodiment of the present invention. Hereinafter, the constituent elements of the semiconductor device 200 shown in FIG. 5 are identical or similar to the ones shown in FIGS. 1 to 4 except for the edge isolation portions EISO′, FIGS. 1 to 4 may be referred to.

Referring to FIG. 5, the semiconductor device 200 may include a plurality of isolation portions ISO and edge isolation portions EISO′. The isolation portions ISO may be disposed in the cell array portion CAR. The isolation portions ISO may be disposed between the neighboring bit lines BL in the third direction D3. The isolation portions ISO may be disposed between the neighboring capacitors CAP in the third direction D3. The edge isolation portions EISO′ may be disposed at the boundary between the cell array portion CAR and the contact portion CTR. The edge isolation portions EISO′ may not include the protrusions ISP which are shown in FIG. 1. For example, the protrusions may be omitted, and in this case, the word line separation slits WSM1 and WSM2 may further extend toward the cell array portion CAR. A second distance D12 between the word line separation slits WSM1 and WSM2 and the edge isolation portions EISO′ may be closer. Referring back to FIG. 1, when the protrusions ISP exist, the word line separation slits WSM1 and WSM2 and the edge isolation portions EISO may be spaced apart from each other by a first distance D11. The second distance D12 may be smaller than the first distance D11.

FIG. 6 is a plan view illustrating a semiconductor device 300 according to another exemplary embodiment. Hereinafter, as for the constituent elements of the semiconductor device 300 shown in FIG. 6 except for an edge supporter EHSL, FIGS. 1 to 4 may be referred to.

Referring to FIG. 6, the semiconductor device 300 may include an edge supporter EHSL. The edge supporter EHSL may have the same shape as the supporters HSL or VSL. For example, the edge supporter EHSL may be formed in the same shape as the first supporters HSL as shown in FIG. 6. The edge supporter EHSL may extend vertically in the first direction D1 and may extend in a third direction D3, which is parallel to the first supporters HSL, from the perspective of a top view. The edge supporter EHSL may be disposed between a pair of HSL supporters which are adjacent to the edge isolation portions EISO. In the D3 direction, the edge supporter EHSL may be spaced apart from an edge isolation portion EISO on one of its sides and may be spaced apart from and a second supporter VSL on its opposite side. The edge supporter EHSL may be formed of a dielectric material. For example, the edge supporter EHSL may include silicon oxide, silicon carbon oxide, silicon nitride, a low-k material, or a combination thereof. The length of the edge supporter EHSL in the third direction D3 may be shorter than that of the first supporters HSL.

As the edge supporter EHSL is formed, a bending margin of the word line edge portion may be additionally secured.

FIG. 7 is a plan view illustrating a semiconductor device 400 in accordance with another embodiment of the present invention. Hereinafter, as for the constituent elements of the semiconductor device 400 shown in FIG. 7 except for the edge supporter EHSL and the edge isolation portions EISO′, FIGS. 1 to 6 may be referred to.

Referring to FIG. 7, the semiconductor device 400 may include an edge supporter EHSL, a plurality of isolation portions ISO, and a plurality of edge isolation portions EISO′. The isolation portions ISO may be disposed in the cell array portion CAR. The isolation portions ISO may be disposed between the neighboring bit lines BL in the third direction D3. The isolation portions ISO may be disposed between the neighboring capacitors CAP in the third direction D3. The edge isolation portions EISO′ may be disposed at the boundary between the cell array portion CAR and the contact portion CTR. The edge isolation portions EISO′ disposed between the cell array portion CAR and the contact portion CTR may not include protrusions.

As the edge supporter EHSL is formed, a bending margin of the word line edge portion may be additionally secured.

FIG. 8 is a plan view illustrating a semiconductor device 500 in accordance with another embodiment of the present invention. Hereinafter, as for the constituent elements of the semiconductor device 500 shown in FIG. 8 except for the supporters THSL, FIGS. 1 to 7 may be referred to.

Referring to FIG. 8, the semiconductor device 500 may include a plurality of supporters THSL. The supporters THSL may extend vertically in the first direction D1. From the perspective of a top view, the supporters THSL may extend in the third direction D3.

Unlike FIG. 1, the supporters THSL do not include the second supporters VSL. The supporters THSL may correspond to the first supporters HSL shown in FIG. 1, but they may have a larger size (i.e., width in the D2 direction) than that of the first supporters HSL. The supporters THSL may be formed of a dielectric material. For example, the supporters THSL may include silicon oxide, silicon carbon oxide, silicon nitride, a low-k material, or a combination thereof.

According to FIG. 8, since the size of the supporters THSL is increased, the material for forming the supporters THSL may be secured with a gap-fill margin.

According to the above-described embodiments of the present invention, the bending of the word line edge portion may be improved by forming the supporters HSL, VSL, and THSL.

According to the above-described embodiments of the present invention, the reliability of a semiconductor device may be improved because the supporters HSL, VSL, and THSL may suppress the bending of word lines.

While the present invention has been described with respect to the specific embodiments, it will be apparent to those skilled in the art that various changes and modifications may be made without departing from the spirit and scope of the invention.

What is claimed is:

1. A semiconductor device, comprising:
a pair of word line separation slits;
a word line stack disposed between the pair of the word line separation slits and including a plurality of word lines that are vertically stacked;
a plurality of supporters disposed between the word line separation slits and supporting the word line stack; and
contact plugs electrically connected to the word line stack.

2. The semiconductor device of claim 1, wherein the word line stack includes:
a word line main portion, and
a stepped word line edge portion extending from the word line main portion.

3. The semiconductor device of claim 2, further comprising:
a plurality of isolation portions suitable for supporting the word line main portion of the word line stack.

4. The semiconductor device of claim 2, wherein the supporters extend vertically to pass through the word line edge portion of the word line stack.

5. The semiconductor device of claim 1, wherein the supporters may include:
first supporters disposed adjacent to the word line separation slits; and
second supporters disposed adjacent to the contact plugs.

6. The semiconductor device of claim 5, wherein the first supporters and the second supporters are disposed to extend in directions intersecting with each other.

7. The semiconductor device of claim 1, wherein the supporters include a dielectric material.

8. The semiconductor device of claim 1, further comprising:
edge isolation portions spaced apart from the supporters.

9. The semiconductor device of claim 8, wherein the edge isolation portions include:
protrusions disposed adjacent to first-side ends of the word line separation slits.

10. The semiconductor device of claim 8, further comprising:
an edge supporter disposed adjacent to the edge isolation portions.

11. A semiconductor device, comprising:
a pair of word line separation slits;
a cell array portion including a plurality of vertical isolation portions;
a contact portion horizontally spaced apart from the cell array portion;
a word line stack including a word line main portion which is disposed in the cell array portion and a word line edge portion which is disposed between the pair of the word line separation slits;
a plurality of supporters disposed between the word line separation slits and supporting the word line edge portion of the word line stack; and
contact plugs electrically connected to the word line edge portion of the word line stack.

12. The semiconductor device of claim 11, wherein the word line edge portion includes a stepped structure.

13. The semiconductor device of claim 11, wherein the supporters extend vertically to pass through the word line edge portion of the word line stack.

14. The semiconductor device of claim 11, wherein the supporters include:
first supporters disposed adjacent to the word line separation slits; and
second supporters disposed adjacent to the contact plugs.

15. The semiconductor device of claim 14, wherein the first supporters and the second supporters are disposed to extend in directions intersecting with each other.

16. The semiconductor device of claim 11, wherein the supporters include a dielectric material.

17. The semiconductor device of claim 11, further comprising:
edge isolation portions disposed between the cell array portion and the contact portion and spaced apart from the supporters.

18. The semiconductor device of claim 17, wherein the edge isolation portions include:
protrusions disposed adjacent to first-side ends of the word line separation slits.

19. The semiconductor device of claim 17, further comprising:
an edge supporter disposed adjacent to the edge isolation portions, wherein the edge supporter is disposed adjacent to the edge isolation portions.

20. The semiconductor device of claim 11, wherein the cell array portion includes:
a horizontally oriented active layer;
a vertical bit line coupled to a first side of the active layer;
a capacitor coupled to a second side of the active layer; and
a double structure in which the word lines extend horizontally with the active layer interposed therebetween.
